(19) United States
(12) Patent Application Publication
(10) Pub. No.: US 2006/0164110 A1
(43) Pub. Date: Jul. 27, 2006

(54) Semiconductor device and method of fabricating the same

(75) Inventors: Takashi Miyazaki, Kawasaki (JP); Takehiro Kimura, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/336,882

(22) Filed: Jan. 23, 2006

(30) Foreign Application Priority Data
Jan. 25, 2005 (JP) 2005-017465

(51) Int. Cl. G01R 31/02; G01R 31/26

(52) U.S. Cl. 324/754; 324/765

(57) ABSTRACT

A highly-reliable semiconductor device and a method of fabricating the semiconductor device, while stably carrying out IC test, are proposed. A pad portion after an IC test using a probe is covered with a second passivation film. It is therefore made possible to protect the pad, which has partially been thinned by the IC test, from a chemical solution of wet etching used, after the IC test, for removing a barrier metal. This consequently makes it possible to suppress intrusion of a chemical solution through the pad portion into an IC chip. In the semiconductor device, the pad portion provided for the IC test using the probe and the opening provided for formation of the metal bump electrode are separated. It is therefore made possible to suppress any influence of the probe mark produced by the IC test exerted on the geometry of the metal bump electrode.

This application is based on Japanese patent application No. 2005-017465 the content of which is incorporated hereinto by reference.

### DISCLOSURE OF THE INVENTION

1. Field of the Invention

The present invention relates to a semiconductor device and a method of fabricating the same.

2. Related Art

With recent progress in downsizing of semiconductor devices, semiconductor devices with bumps for flip-chip bonding has become more widely used. Bumps for flip-chip bonding, becoming more popular as a result of downsizing of semiconductor devices and increase in the number of pins, are such as Au and solder bumps which can finely be formed by plating.

In IC test of a wafer 70 having a plated bump 62 used as a bump for flip-chip bonding, it has been necessary, as shown in FIG. 15 and FIG. 16, to bring a test probe 66 into direct contact with the plated bump 62. The wafer 70 has an inter-layer insulating film 50 formed so as to contact with the top surface of a silicon substrate (not shown), and an IC topmost layer interconnection 52 provided so as to contact with the top surface of the inter-layer insulating film 50, and connected to internal circuits (not shown). The wafer 70 has also a first passivation film 56 protecting the IC topmost layer interconnection 52, a second passivation film 58 provided so as to contact with the top surface of the first passivation film 56, and a barrier metal 60 provided for the purpose of suppressing diffusion of solder from the plated bumps 62 into the IC topmost layer interconnection 52. How successfully damages to the bumps, electrode pads and wafer interconnections can be reduced so as to ensure a stable IC test is essential in the test process, but the method shown in FIG. 15 and FIG. 16 has undesirably caused a probe mark 64 on the plated bump 62.

One example of the IC test method for flip-chip-type semiconductor device using solder bumps, aimed at suppressing production of the probe mark 64 on the plated bumps 62 and adhesion of solder onto the probe, ascribable to the direct contact of the test probe 66 onto the solder bumps, and suppressing consequent contact failure due to variation in height of the plated bumps 62, is found in Japanese Laid-Open Patent Publication 2002-90422.

FIG. 7 to FIG. 13 show a process flow of fabrication of a semiconductor device illustrated in FIG. 2 of Japanese Laid-Open Patent Publication 2002-90422.

First, an aluminum interconnection 20 and a passivation film 34 are provided on a semiconductor wafer 1 (FIG. 7). Next, a barrier metal layer 5a is provided so as to cover the aluminum interconnection 20 and the passivation film 34 (FIG. 8). Next, a plate-masking resist 6 is provided on the barrier metal layer 5a (FIG. 9). A metal plated layer 7a is then provided at sites having no plate-masking resist 6 provided thereon by the electrolytic plating technique (FIG. 10). Next, the plate-masking resist 6 is removed (FIG. 11), and a portion of the barrier metal layer 5a other than the portion to be left as a barrier metal 5 is removed (FIG. 12). Next, the metal plated layer 7a is re-flowed to thereby form a solder ball 7 (bump) (FIG. 13).

A sectional view and a top view of the semiconductor device according to a technique described in Japanese Laid-Open Patent Publication 2002-90422 are shown in FIG. 14A and FIG. 14B, respectively. In the technique described in this patent publication, a pad opening 21 for bump formation and a pad opening 22 for test use are formed at the same time on a single aluminum interconnection 20. This configuration, allowing IC test first on the test pad, and formation of the bump then on the bump-forming pad, makes it possible to suppress any influence exerted on the bump-forming pads and the bumps.

The conventional technique, however, still remains a room for improvement in the aspects below.

The technique described in the second embodiment of the above patent publication allows the barrier metal to remain also on the pad opening 22 for test use as shown in FIG. 17, when the barrier metal is etched in the process flow for bump formation (see FIG. 12), in order to protect the test pad, but this consequently makes it impossible for the probe to contact with the Al pad, and only allows contact with the hard barrier metal. This raised a problem of destabilizing the probe contact.

For the case where the IC test is carried out through the pad opening 22 for test use before the bump is formed in the second embodiment of the above-described patent publication, the pad for test use has a surface irregularity ascribable to the probe mark, and this degrades the film quality of the barrier metal formed thereon, so that a problem has arisen in that the barrier metal was incapable of fully block intrusion of corrosive substance or contaminants into integrated circuit even if it was formed on the test pad.

### SUMMARY OF THE INVENTION

According to the present invention, there is provided a semiconductor device which includes:

a semiconductor substrate;

an interconnection layer provided on the semiconductor substrate; and

a pad electrode provided on the interconnection layer;

wherein the pad electrode includes a probe contact area and a bonding area, and

the probe contact area is covered with a protective film composed of an insulating film.

The probe contact area in the present invention is covered with the protective film. It is therefore made possible to suppress migration of any chips of the pad electrode, possibly caused by contact of the probe with the probe contact area, out from the probe contact area.

In the present invention, the bump may be provided in the bonding area, wherein this makes it possible, in the process of bump formation, to suppress intrusion of an etching solution used for removing the metal film composing the barrier metal, through the probe contact area into the IC chip, and to thereby provide a highly-reliable semiconductor device. Division of the pad electrode into the probe contact area and the bump-forming bonding area also makes it possible to suppress any influence of the probe mark produced by the IC test exerted on the bump geometry.

According to the present invention, there is also provided a method of fabricating a semiconductor device which includes:

forming an interconnection layer on a semiconductor substrate, and forming on the interconnection layer a pad electrode having a probe contact area and a bonding area;

bringing a probe into contact with the probe contact area; and

forming a protective film composed of an insulating film so as to cover the probe contact area.

In the present invention, bringing the probe into contact with the pad electrode in the probe contact area ensures stable contact of the IC test probe with the pad electrode. This makes it possible to fabricate a semiconductor device while stably carrying out the IC test.

The present invention may further include, subsequently to the step of forming the protective film, a step of forming a bump on the bonding area, wherein this makes it possible to fabricate a semiconductor device successfully suppressed in any influences of the probe mark, caused by the IC test, exerted on the bump geometry.

The present invention can provide a highly-reliable semiconductor device. The present invention can also fabricate a semiconductor device while stably carrying out the IC test.

### BRIEF DESCRIPTION OF THE DRAWINGS

The above and other objects, advantages and features of the present invention will be more apparent from the following description taken in conjunction with the accompanying drawings, in which:

FIG. 1 is a sectional view schematically showing a semiconductor device of an embodiment;

FIG. 2 to FIG. 6 are schematic sectional views showing process steps of fabricating a semiconductor device of the embodiment:

FIG. 7 to FIG. 13 are schematic sectional views showing process steps of fabricating a semiconductor device according to a conventional technique;

FIG. 14 is a schematic drawing showing a semiconductor device according to a conventional technique;

FIG. 15 is a sectional view showing a probe test method for a semiconductor device according to a conventional technique;

FIG. 16 is a sectional view schematically showing a semiconductor device according to a conventional technique; and

FIG. 17 is a sectional view schematically showing a semiconductor device according to another conventional technique.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Next paragraphs will describe an embodiment of the present invention, referring to the attached drawings. It is to be noted that same constituents will be given with the same reference numerals in all drawings, allowing omission of repetitive explanation therefor.

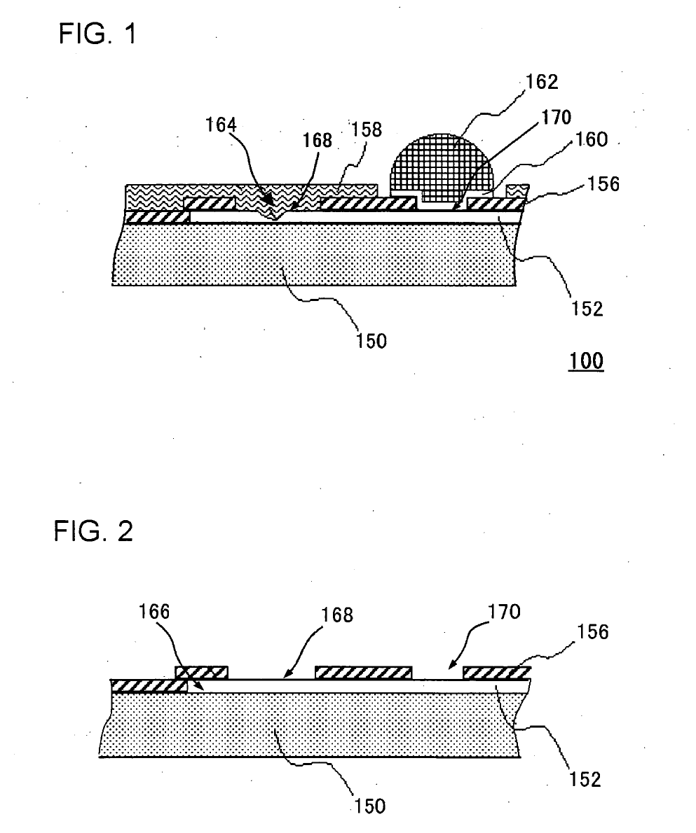

A semiconductor device 100 shown in FIG. 1 has a semiconductor substrate (silicon substrate 150), an interconnection layer provided on the semiconductor substrate, and a pad electrode (IC topmost layer interconnection 152) provided on the interconnection layer, wherein the pad electrode includes a probe contact area 168 and a bonding area 170, and the probe contact area 168 is covered with a protective film (second passivation film 158) composed of an insulating film.

FIG. 1 is a sectional view showing the semiconductor device 100 according to this embodiment.

The semiconductor device 100 is configured by the silicon substrate 150, an IC topmost layer interconnection 152 provided so as to contact with the top surface of the silicon substrate 150, a first passivation film 156 provided so as to cover a part of the IC topmost layer interconnection 152, the second passivation film 158, a barrier metal 160, and a metal bump electrode 162.

On the top portion of the silicon substrate 150, there are provided interconnection layers and inter-layer insulating films, although not shown.

The IC topmost layer interconnection 152 is typically composed of an aluminum-containing metal or the like, and is connected to the an internal circuit (not shown), which is an integrated circuit (IC). The IC topmost layer interconnection 152 has an integrated geometry, and includes the probe contact area 168 and the bonding area 170. The probe contact area 168 composes a part of the IC topmost layer interconnection 152, and is a pad region with which a probe is brought into contact in the IC test judging acceptance or rejection of the internal circuit. The probe contact area 168 after the probe test judging acceptance or rejection of the internal circuit has a probe mark 164 formed thereon as a probe contact mark.

The first passivation film 156 is typically composed of a silicon oxide film such as SiO₂, and has a function of covering and thereby protecting the IC topmost layer interconnection 152. The first passivation film 156 does not cover the IC topmost layer interconnection 152 in the probe contact area 168 and in the bonding area 170.

The second passivation film 158 is typically composed of polyimide, and covers and protects the IC topmost layer interconnection 152 exposed in the probe contact area 168 having the probe mark 164 remained thereon. The film also covers the first passivation film 156 in a portion other than the bonding area 170. The second passivation film 158 is formed after the IC test which is carried out by bringing a probe into contact with the probe contact area 168.

The bonding area 170 composes a part of the IC topmost layer interconnection 152, and is a pad region on which the metal bump electrode 162 is formed so as to contact with the top surface thereof, while placing the barrier metal 160 in between.

The barrier metal 160 is provided so as to cover the IC topmost layer interconnection 152 exposed in the bonding area 170. The barrier metal 160 is composed of a single layer or a plurality of metal layers of Ni, Cu, Ti and so forth, and had a function of suppressing diffusion of components of the metal bump electrode 162, described later, into the IC topmost layer interconnection 152.

The metal bump electrode 162 is provided so as to cover the top surface of the barrier metal 160. In this embodiment, the metal bump electrode 162 is composed of solder, and is used for connection with the external.

Next paragraphs will describe a fabrication process of the semiconductor device 100, referring to FIG. 2 to FIG. 6.

FIG. 2 shows a sectional structure of a wafer having the internal circuit (not shown) formed therein, before the metal bump electrode 162 is formed.

The wafer is formed by the method described below. First, on the silicon substrate 150 having an interconnection layer (not shown) formed on the upper region thereof, the IC topmost layer interconnection 152 composed of aluminum having the same potential is formed by sputtering. Next, the first passivation film 156 is provided, typically by the CVD process, so as to cover the IC topmost layer interconnection 152. Next, a resist is patterned, and light-exposed portion thereof is wet-etched to thereby provide an opening through which the probe contact area 168 and the bonding area 170 are opened.

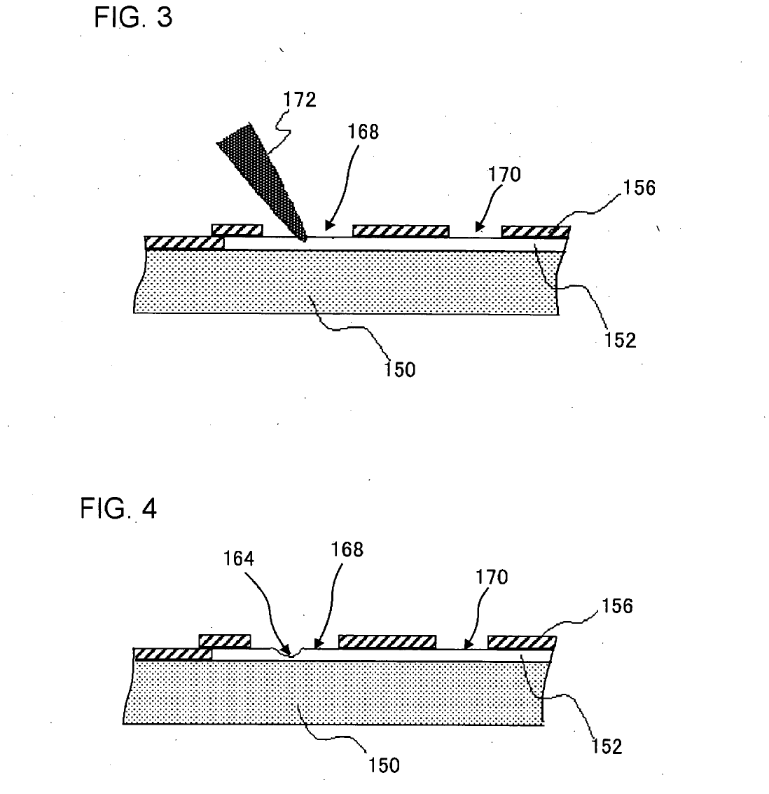

Next, as shown in FIG. 3, a probe 172 is brought into contact with the IC topmost layer interconnection 152 exposed in the probe contact area 168 so as to measure the electrical characteristics, to thereby enable an on-wafer probe test judging acceptance or rejection of the internal circuit (not shown).

As a consequence, the IC topmost layer interconnection 152 exposed in the probe contact area 168 has the probe mark 164 produced thereon, as shown in FIG. 4, due to removal of aluminum by the probe 172.

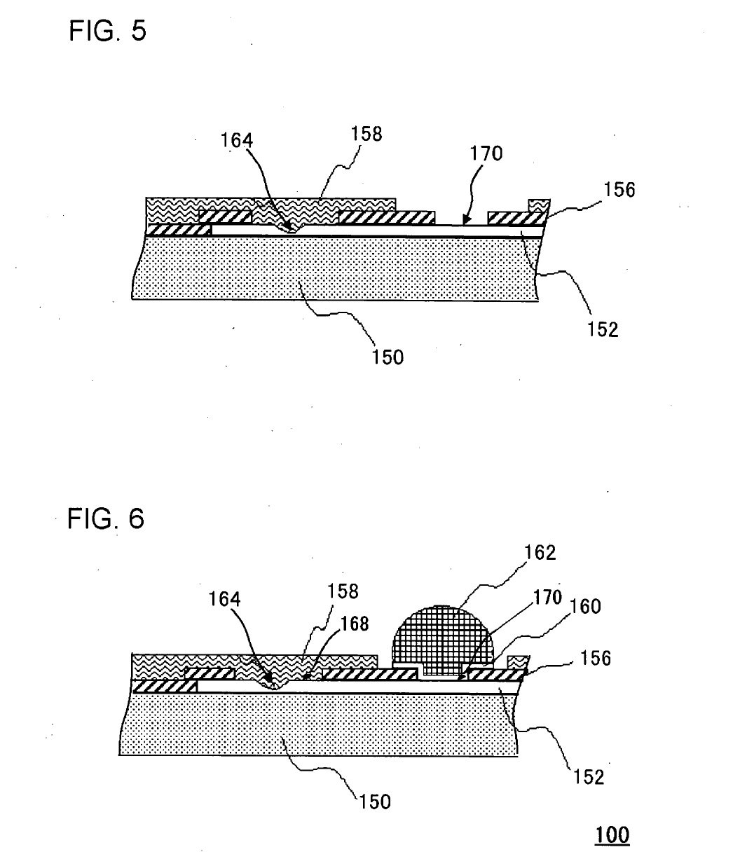

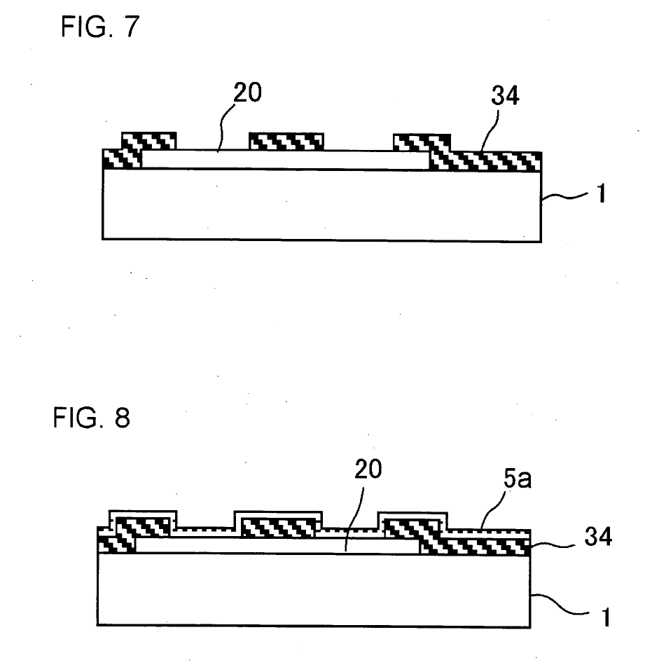

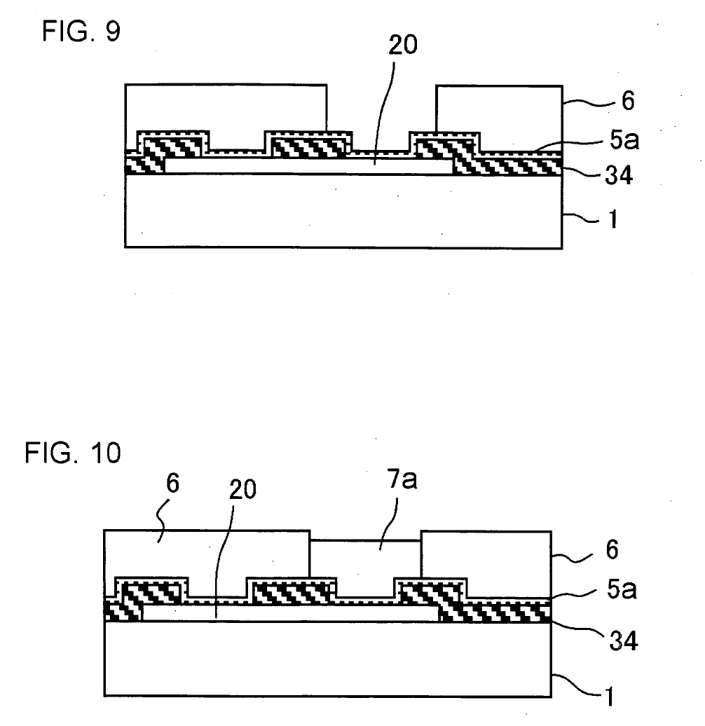

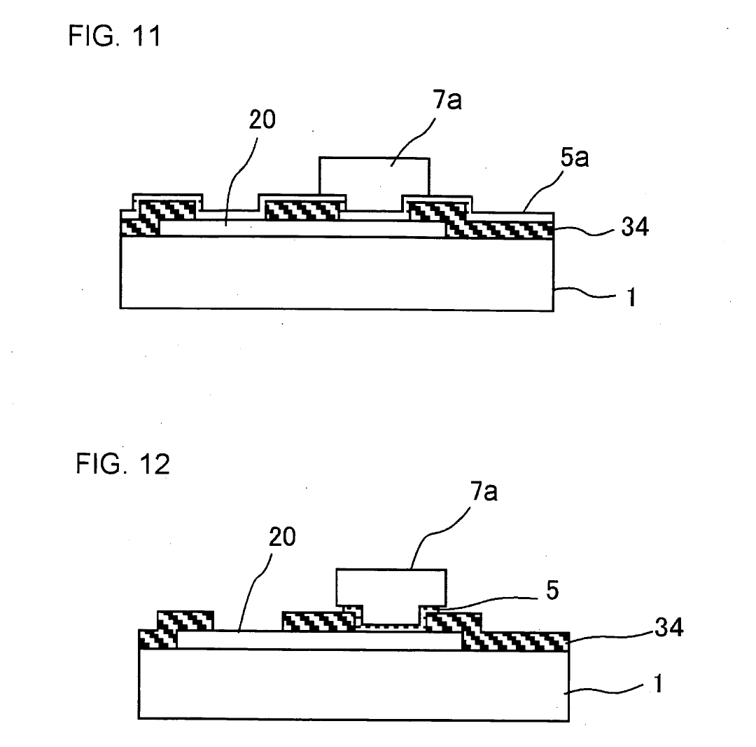

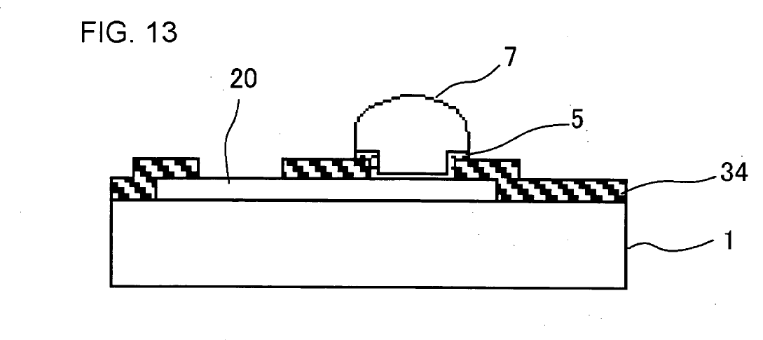

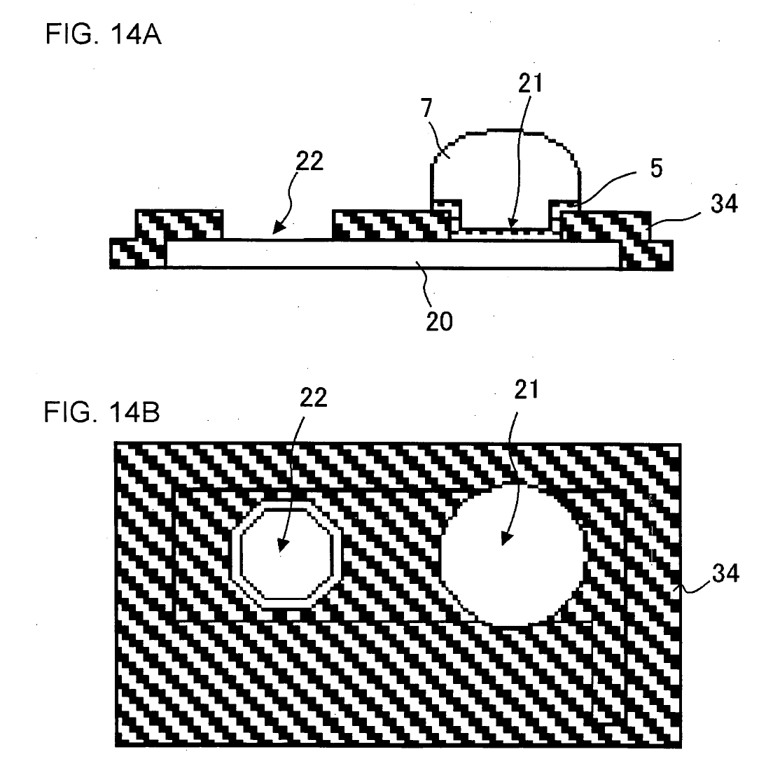

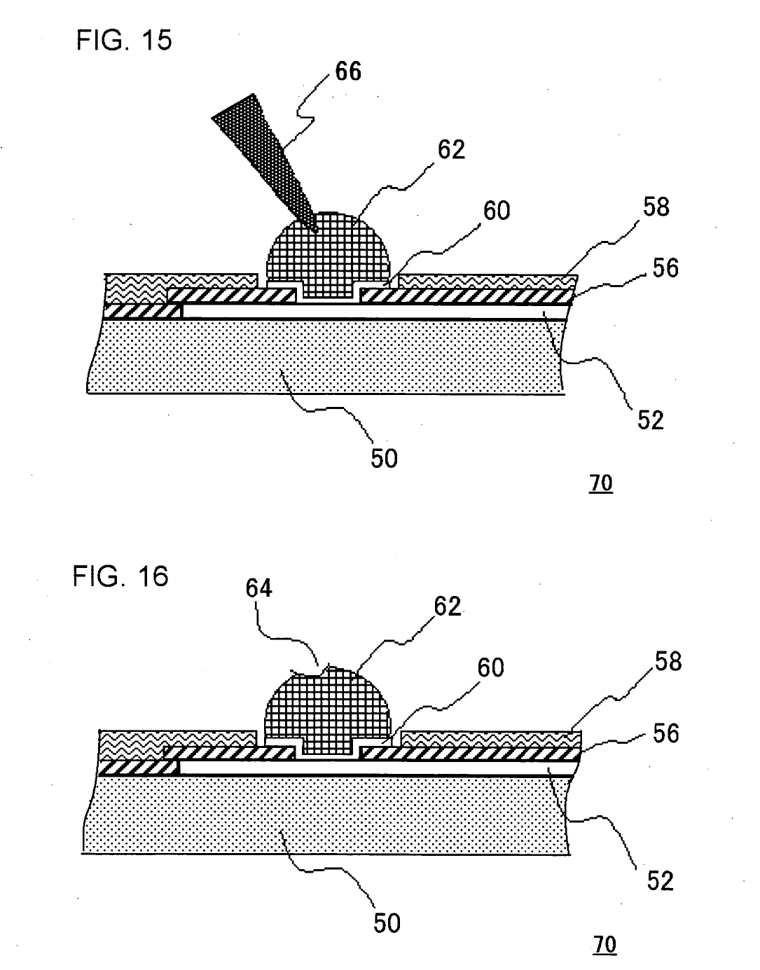

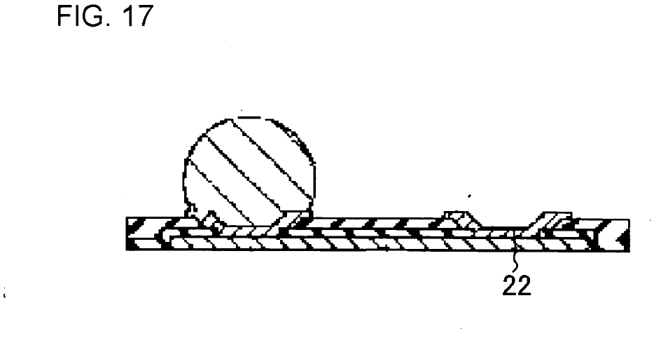

Next, the second passivation film 158 is formed so as to cover the probe contact area 168 and to expose the bonding area 170 (FIG. 5). A specific method therefor is exemplified as follows. First, a coated film is formed over the entire surface typically by the spin coating process, and a resist is formed on the resultant coated film. Next, the resist is light-exposed through a mask and pattered, the second passivation film 158 is then etched off in a portion fallen in the bonding area 170, so as to expose the bonding area 170. An etching solution used herein is such as being capable of removing the second passivation film 158 but incapable of removing the first passivation film 156.

Next, the barrier metal 160 is formed so as to cover the top surface of the bonding area 170, a part of the top surface of the first passivation film 156, and the top surface of the second passivation film 158, and is then removed by wet etching in the portion other than the bonding area 170. Next, the metal bump electrode 162 is formed so as to cover the top surface of the barrier metal 160 (FIG. 6).

The semiconductor device 100 is thus finished by the process descried in the above.

Effect of the semiconductor device 100 will be described below.

In the semiconductor device 100, the pad portion after the IC test using a probe is covered with the second passivation film 158. It is therefore made possible to protect the probe contact area 168 (pad portion), which has partially been thinned by the IC test, from a chemical solution for wet etching used for removing the barrier metal 160. As a consequence, intrusion of the chemical solution into the IC chip through the pad portion can be suppressed. Covering the probe contact area 168 after the IC test with the second passivation film 158 also makes it possible to suppress migration of debris (chips) of the IC topmost layer interconnection 152, which may possibly be produced by contact of the probe in process of the IC test, to the external of the probe contact area 168. In the semiconductor device 100, the region (the IC topmost layer interconnection 152 exposed in the probe contact area 168) provided for the IC test using a probe (the test judging acceptance or rejection of the internal circuit), and the region (the IC topmost layer interconnection 152 exposed in the bonding area 170) provided for formation of the metal bump electrode 162 are separated. This makes it possible to suppress any influence of the probe mark 164 produced in the IC test exerted on the geometry of the metal bump electrode 162.

It is also made possible to stably bring the probe into contact with the pad portion, unlike the technique described in Japanese Laid-Open Patent Publication 2002-90422 in which the probe had to be brought into contact with the barrier metal having a large hardness. The IC test can, therefore, be carried out in a stable manner.

In the semiconductor device 100, aluminum is used as a material composing the IC topmost layer interconnection 152. Aluminum, known as a soft metal material, allows the probe in the IC test to contact with an unoxidized fresh section of aluminum. This makes it possible to further stabilize electrical contact between the probe and the IC test pad.

In the semiconductor device 100, solder is used as a material composing the metal bump electrode 162. It is, therefore, made possible to improve the contact performance between an interconnection and so forth used for connection with the external and the metal bump electrode 162.

The embodiment having been described in the above referring to the attached drawings is only a part of examples of the present invention, allowing adoption of any various configurations other than those described in the above.

For example, the above embodiment has explained a case in which the IC topmost layer interconnection 152 was composed of an aluminum-containing metal, whereas any other conductors are allowable so far as they can be electrically connected with the integrated circuit, and can be provided on the silicon substrate 150.

The above embodiment has explained a case in which solder was used as a material composing the metal bump electrode 162, whereas the material composing the metal bump electrode may be gold, copper, or combination of these or a plurality of metals. Use of gold herein as a material composing the metal bump electrode makes it possible to bond the interconnection for external interconnection with the bump, by a more simple bonding process such as conventionally-applied heat sealing, ultrasonic-wave-assisted heat sealing or the like.

The effect described in the above embodiment can be obtained even for the case where an IC topmost layer interconnection having the probe contact area and the bonding area disposed in a discrete manner is used. A larger effect will, however, be obtained by the IC topmost layer interconnection 152 having the probe contact area 168 and the bonding area 170 communicated in an integrated manner as described in the above embodiment.

It is apparent that the present invention is not limited to the above embodiments, that may be modified and changed without departing from the scope and spirit of the invention.

What is claimed is:

1. A semiconductor device comprising:
a semiconductor substrate;
an interconnection layer provided on said semiconductor substrate; and
pad electrode provided on said interconnection layer;
wherein said pad electrode comprises a probe contact area and a bonding area, and
said probe contact area is covered with a protective film composed of an insulating film.

2. The semiconductor device as claimed in claim 1, wherein said bonding area is provided with a bump.

3. The semiconductor device as claimed in claim 1, wherein said interconnection layer is connected to an integrated circuit, and
said probe contact area is a test pad through which acceptance or rejection of said integrated circuit is judged.

4. The semiconductor device as claimed in claim 1, wherein said probe contact area has a probe contact mark.

5. The semiconductor device as claimed in claim 1, wherein said pad electrode is composed of an aluminum-containing metal.

6. The semiconductor device as claimed in claim 2, wherein said bump is composed of a solder.

7. The semiconductor device as claimed in claim 2, wherein said bump is composed of gold.

8. A method of fabricating a semiconductor device comprising:
forming an interconnection layer on a semiconductor substrate, and forming on said interconnection layer a pad electrode having a probe contact area and a bonding area;
bringing a probe into contact with said probe contact area; and
forming a protective film composed of an insulating film so as to cover said probe contact area.

9. The method of fabricating a semiconductor device as claimed in claim 8, further comprising, subsequently to said forming the protective film, forming a bump on said bonding area.
